(19) United States
(12) Patent Application Publication
(10) Pub. No.: US 2026/0160714 A1
(43) Pub. Date: Jun. 11, 2026

(54) NAVIGATION ACCURACY FOR ARRAY SCANNING

(71) Applicant: Aplied Materials Israel Ltd., Rehovot (IL)

(72) Inventors: Ofir Greenberg, Haniel (IL); Benny Shamay, Rehovot (IL)

(73) Assignee: Applied Materials Israel Ltd., Rehovot (IL)

(21) Appl. No.: 18/970,767

(22) Filed: Dec. 5, 2024

(51) Int. Cl. G01N 23/18; H01J 37/22; H01J 37/26; H01J 37/28

(52) U.S. Cl. CPC G01N 23/18; H01J 37/222; H01J 37/265; H01J 37/28

(57) ABSTRACT

A system for navigation accuracy, the system includes a memory unit and a location circuit. The memory unit is configured to store scanning electron microscope (SEM) images of tiles of a sample. The tiles belong to a periodic array of structural elements that exhibit at least one microscopic dimension. The tiles include a reference tile of a known location and location error prone tiles. There is an overlap region between each set of adjacent tiles. Each overlap region includes an overlap segment of one of the structural elements. The location circuit is configured to determine locations of the tiles based on locations of sets of adjacent tiles. The location of each set is determined based on (i) a process variation that appears in an overlap segment of the set, (ii) the known location, and (iii) a presence of the overlap segment of the set within each tile of the set.

### BACKGROUND OF THE INVENTION

Samples such as integrated circuits are evaluated by using charged particle tools such as a scanning electron microscope (SEM). An example of a scanning electron microscope is the SEMVISION™ manufactured by APPLIED MATERIALS™Inc. of San Jose, California.

The scanning electron microscope is configured to perform multiple scan iterations related to multiple tiles of a sample, while aggregating location errors that may lead to measurement errors.

There is a growing need to achieve navigation accuracy during the scanning of the multiple tiles, especially when the multiple tiles belong to periodic array of structural elements that exhibit at least one microscopic dimension.

### BRIEF SUMMARY OF THE INVENTION

According to an embodiment, there is provided a system for navigation accuracy, the system includes a memory unit and a location circuit that includes one or more integrated circuits. The memory unit is configured to store SEM images of tiles of a sample. The tiles belong to a periodic array of structural elements that exhibit at least one microscopic dimension. The tiles include a reference tile of a known location and location error prone tiles. There is an overlap region between each set of adjacent tiles. Each overlap region includes an overlap segment of one of the structural elements. The location circuit is configured to determine locations of the tiles based on locations of sets of adjacent tiles. The location circuit is configured to determine the location of each set based on (i) a process variation that appears in an overlap segment of the set, (ii) the known location, and (iii) a presence of the overlap segment of the set within each tile of the set.

According to an embodiment, there is provided a method for navigation accuracy. The method includes:
a. Obtaining SEM images of tiles of a sample. The tiles belong to a periodic array of structural elements that exhibit at least one microscopic dimension. The tiles include a reference tile of a known location and location error prone tiles. There is an overlap region between each set of adjacent tiles. Each overlap region includes an overlap segment of one of the structural elements.
b. Determining, for each set and by a location circuit that includes one or more integrated circuits, the locations of the set based on (i) a process variation that appears in an overlap segment of the set, (ii) the known location, and (iii) a presence of the overlap segment of the set within each tile of the set.
c. Determining, the locations of the tiles based on the location of each set.

According to an embodiment, there is provided a non-transitory computer readable medium for navigation accuracy, the non-transitory computer readable medium stores instructions that once executed by a system, cause the system to:
a. Obtain SEM images of tiles of a sample. The tiles belong to a periodic array of structural elements that exhibit at least one microscopic dimension. The tiles include a reference tile of a known location and location error prone tiles. There is an overlap region between each set of adjacent tiles. Each overlap region includes an overlap segment of one of the structural elements.
b. Determine, for each set and by a location circuit of the system, the locations of the set based on (i) a process variation that appears in an overlap segment of the set, (ii) the known location, and (iii) a presence of the overlap segment of the set within each tile of the set; wherein the location circuit includes one or more integrated circuits.
c. Determine the locations of the tiles based on the location of each set.

### BRIEF DESCRIPTION OF THE DRAWINGS

The subject matter regarded as the invention is particularly pointed out and distinctly claimed in the concluding portion of the specification. The invention, however, both as to organization and method of operation, together with specimen s, features, and advantages thereof, may best be understood by reference to the following detailed description when read with the accompanying drawings in which:

FIGS. 1A and 1B illustrate examples of a SEM and of a system for navigation accuracy;

FIG. 2 illustrates an example of a SEM;

FIG. 3 illustrates an example of a method;

FIG. 4 illustrates an example of tiles;

FIG. 5 illustrates an example of tiles; and

FIG. 6 illustrates an example of tiles.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

According to an embodiment there is provided a method, a system and a non-transitory computer readable medium for providing navigation accuracy when scanning multiple tiles of the sample that belong to periodic array of structural elements that exhibit at least one microscopic dimension—and lack visible anchors.

The navigation accuracy is obtained by accurately determining the locations of the tiles based on overlap segments within overlap areas between sets of adjacent tiles and process variations of the overlap segments. A location of a tile may be a location of any pixel with the tile—for example a location of a pixel within an overlap area between the tile and another adjacent tile, a location of pixel outside the overlap area, a location of any corner of the tile, a location of the center of the tile, a location of a suspected defect within a tile, and the like.

Once the location of a tile is known, the points of tile that are scanned by the electron beam are known and pixels of a SEM image of the tile are known.

According to an embodiment the set of tiles is a pair of tiles—or more than a pair of tiles.

According to an embodiment the system is a SEM or belongs to a SEM.

According to an embodiment the system is a stand alone system that does not belong to the SEM and includes a memory unit and a location circuit that includes one or more integrated circuits.

According to an embodiment there is a maximal allowable location error (which is defined in any manner—for example by a manufacturer of the sample or by a client of the sample), and the tiles are shaped and sized to guarantee that the location aggregated while scanning a tile does not exceed the maximal allowable location error.

According to an embodiment there is a maximal allowable location error is small enough to distinguish between two overlap segments located within the same overlap region—in order to accurately map a single overlap segment that is located in the tiles the share the overlap area.

According to an embodiment the overlap areas are shaped and sized to include at least one overlap segment within each overlap region.

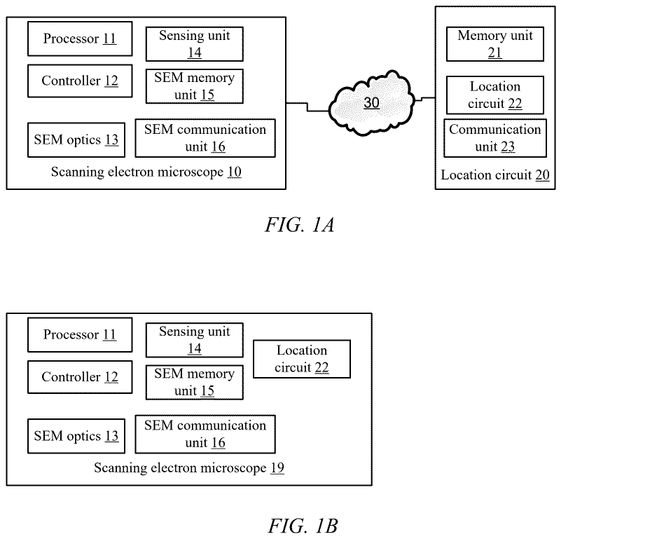

FIGS. 1A and 1B illustrate examples of a SEM 10 and system 20 for navigation accuracy.

System 20 includes a memory unit 21, a location circuit 22 and a communication unit 23 configured to allow communication between the memory unit 21 and the location circuit 22 and/or allow communication with other units or systems.

Memory unit 21 is illustrated as storing SEM images 40 of tiles.

According to an embodiment, memory unit 21 stores all SEM images 40 concurrently.

According to an embodiment, memory unit 21 stores only a portion of all SEM images at once, and may be dynamically fed by the portions required for processing.

Memory unit 21 can be any type of hardware memory unit: a volatile memory unit, a non-volatile unit, a random access memory unit, a dynamic random access memory unit, one or more disks, one or more solid stage drives (SSDs), a memristor based memory unit, a magnetic memory unit, a flash memory unit, and the like.

Location circuit 22 includes one or more processing circuits that in turn may be implemented as a central processing unit (CPU), and/or one or more other integrated circuits such as application specific integrated circuits (ASICs), field programmable gate arrays (FPGAs), full-custom integrated circuits, graphic processing units (GPUs), and the like.

According to an embodiment, SEM 10 includes (a) a processor 11 that may have image processing capabilities and includes one or more processing circuits, (b) a controller 12 for controlling the SEM, (c) SEM optics 13 that is configured to scan the tiles of the sample with an electron beam, (d) a sensing unit 14 that is configured to detect particles emitted due to the scan and generate detection signals indicative of the structural elements within the tiles of the sample, (e) SEM memory unit 15 and (f) SEM communication unit 16.

Processor 11 includes one or more processing circuits that in turn may be implemented as a central processing unit (CPU), and/or one or more other integrated circuits such as application specific integrated circuits (ASICs), field programmable gate arrays (FPGAs), full-custom integrated circuits, graphic processing units (GPUs), and the like.

In the example of FIG. 1A, system 20 does not belong to SEM 10 but is in communication with SEM 10 via network 30. Network 30 may be any type of network: wired, wireless, a local area network, the Internet, and the like.

In the example of FIG. 1B, system 20 belongs to SEM 19, memory unit 21 of system 20 is not shown as in this example the memory unit is included in SEM memory unit 15 (which can be any type of hardware memory unit as described above with respect to memory unit 21), and communication unit 22 of example (a) is not shown in this example as the communication unit is included in SEM communication unit 16. The location circuit 22 may be included in processor 11, but for brevity of explanation it is illustrated as a separate unit.

According to an embodiment, the SEM includes a processing unit that is configured to perform image processing and also to accurately determine the location of tiles.

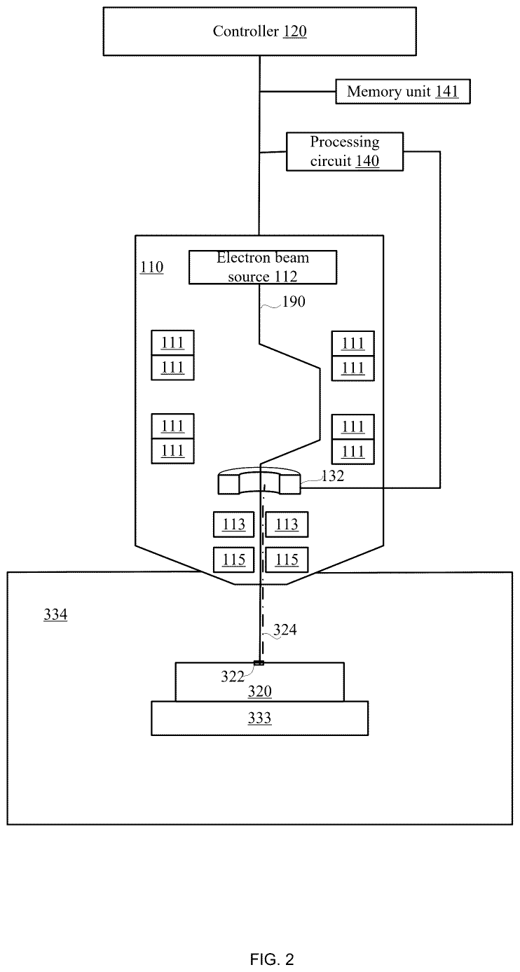

FIG. 2 illustrates an example of SEM 100 and sample 320.

In FIG. 2, SEM 100 uses an electron beam 190 that illuminates a tile 322 of sample 320, having electrons 324 from the tile reach secondary electron sensor 132.

SEM 100 is illustrated as including:
a. Column 110.
b. SEM memory unit 141 for storing instructions and data.
c. Controller 120, that is configured to generate control signals that control the scanning of tiles—such as tile 322 by electron beam 190. According to an embodiment, different tiles are scanned by introducing, under the control of controller 120, a relative movement between the sample and the column. According to an embodiment, the scanning of different tiles does not involve introducing a mechanical movement.
d. A sensing unit that includes one or more sensors such as secondary electron sensor 132 located within column 110.
e. A processor 140 that is configured to convert sensor signals to frames and to images.
f. Vacuum chamber 334 in which the sample is located.
g. Mechanical stage 333 for supporting the sample and for moving the sample.

According to an embodiment, the one or more detectors of the sensing unit may include one or more secondary electron detectors, one or more backscattered electron detectors, and the like. Detectors for detecting photons and additionally or alternatively x-rays may also be included in the charged particle evaluation system. Examples of a column 110 that includes multiple sensors are illustrated in U.S. Pat. No. 7,847,267 of Shemesh et al. Any detector of the SEM may be located within the column or outside the column. A detector may include a single sensing segment, may include multiple sensing segments, maybe a part of an array of sensors, and the like.

According to an embodiment, column 110 includes electron optics (forming at least a part of the SEM optics) such as electron beam source 112 and electron beam manipulation optics that is configured to propagate the electron beam 190 through the column till exiting the column.

The electron beam manipulation optics may include deflection lenses, focusing lenses, electron beam collimating optics, electron beam shaping optics, and the like. Examples of a column 110 that includes multiple deflection coils for double deflecting an electron beam are illustrated in U.S. Pat. No. 7,847,267 of Shemesh et al.

FIG. 2 illustrates the electron beam manipulation optics as including:
a. Bypass magnetic scan coils 111 that are configured to direct the electron beam along a bypass path.
b. Objective lens 113 that is configured to focus the electron beam on the tile 322 of sample 320.
c. Deflector lenses 115 for deflecting the electron beam according to a scan pattern.

An optical axis of the electron beam 190 is a vertical axis through which the electron beam propagated before the bypassing and after the bypassing.

The bypass magnetic scan coils 111 are configured to: (i) tilt the electron beam at a first direction, (ii) tilt the electron beam at an opposite direction such as to propagate along a secondary optical axis that is parallel to the optical axis but spaced apart from the optical axis, (iii) tilt the electron beam at a second direction, towards the optical axis, and (iv) tilt the electron beam, at a direction opposing the second direction, such as to propagate along the optical axis. A system and method for double tilt is described at U.S. Pat. No. 6,674,075 of Petrov et al. and is incorporated herein by reference.

The SEM may also include a vacuum system (not shown) configured to maintain the column is maintained in vacuum, a high power supply unit (not shown) configured to provide high voltage signals to accelerate the electron beam and to decelerate the electron beam.

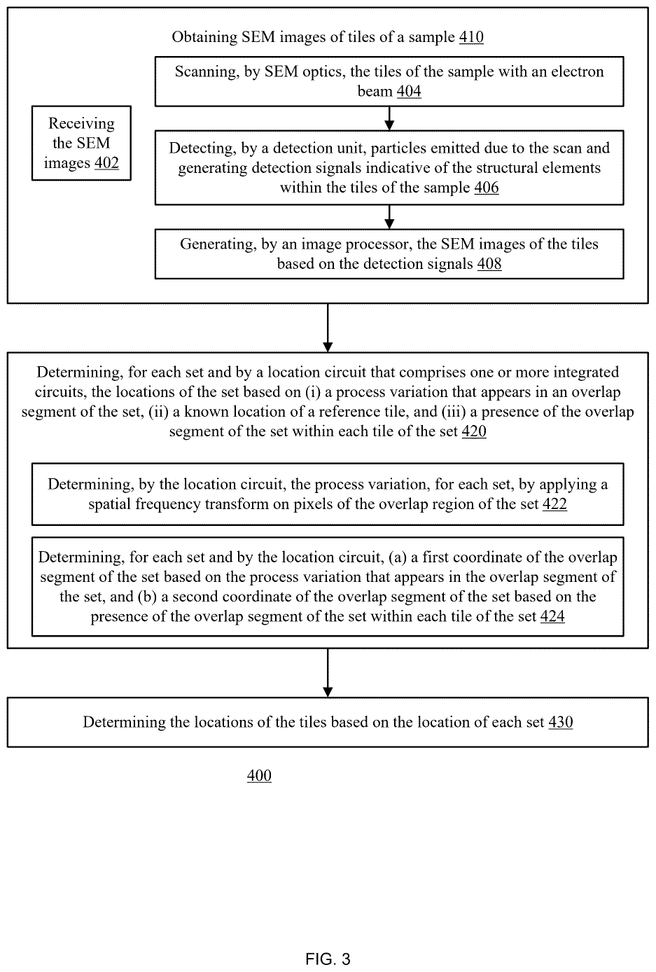

FIG. 3 illustrates an example of method 400 for navigation accuracy.

According to an embodiment, method 400 includes step 410 of obtaining SEM images of tiles of a sample. The tiles belong to a periodic array of structural elements that exhibit at least one microscopic dimension. The tiles include a reference tile of a known location and location error prone tiles. There is an overlap region between each set of adjacent tiles. Each overlap region includes an overlap segment of one of the structural elements. According to an embodiment the known location is taken from computer aided design information.

According to an embodiment step 410 includes step 402 of receiving he SEM images.

According to an embodiment, step 420 is followed by determining, for each set and by a location circuit that comprises one or more integrated circuits, the locations of the set based on (i) a process variation that appears in an overlap segment of the set, (ii) the known location, and (iii) a presence of the overlap segment of the set within each tile of the set.

According to an embodiment, and assuming that a location of a first tile of the set is known—then the location (at least one coordinate) of the overlap segment within the first tile of the set is also known. Accordingly, the location (at least one coordinate) of the overlap segment within a second tile of the set is also known to be equal to the location of the overlap segment within the first tile. According to an embodiment, the process variation provides additional information (for example another coordinate) about the location of the overlap segment, and the known location is used as an anchor.

According to an embodiment the process variation is a result of changes in a manufacturing process conditions such as temperature, pressure, dopant concentration, one or more illumination properties, mechanical inaccuracies and the like. A process variation of an overlap segment introduced changes (such as shape changes—such as orientation deviations, changes in location and/or shape of edges, and the like) between one overlap segment to the other. According to an embodiment, the spatial frequencies of process variations are lower than the spatial frequencies of foreign particles.

According to an embodiment, step 420 is followed by step 430 of determining the locations of the tiles based on the location of each set.

According to an embodiment, step 430 includes determining locations of one or more tiles that belong to the same set of adjacent tiles as the reference tiles—and then propagating the determined locations to other sets of adjacent tiles.

According to an embodiment, step 420 includes step 422 of determining, by the location circuit, the process variation, for each set, by applying a spatial frequency transform on pixels of the overlap region of the set.

According to an embodiment, the spatial frequency transform is a two-dimensional spatial frequency transform. Using a two-dimensional spatial frequency transform is beneficial as the orientation of one or more axes of repetition of the structural elements of the array may be unknown or may change from one array of a die to another, and two-dimensional spatial frequency transform covers different orientations.

According to an embodiment, step 420 includes step 424 of determining, for each set and by the location circuit, (a) a first coordinate of the overlap segment of the set based on the process variation that appears in the overlap segment of the set, and (b) a second coordinate of the overlap segment of the set based on the presence of the overlap segment of the set within each tile of the set.

According to an embodiment, the structural elements are arranged in a repeating pattern along a single axis of repetition, and the second coordinate is a single axis of repetition coordinate.

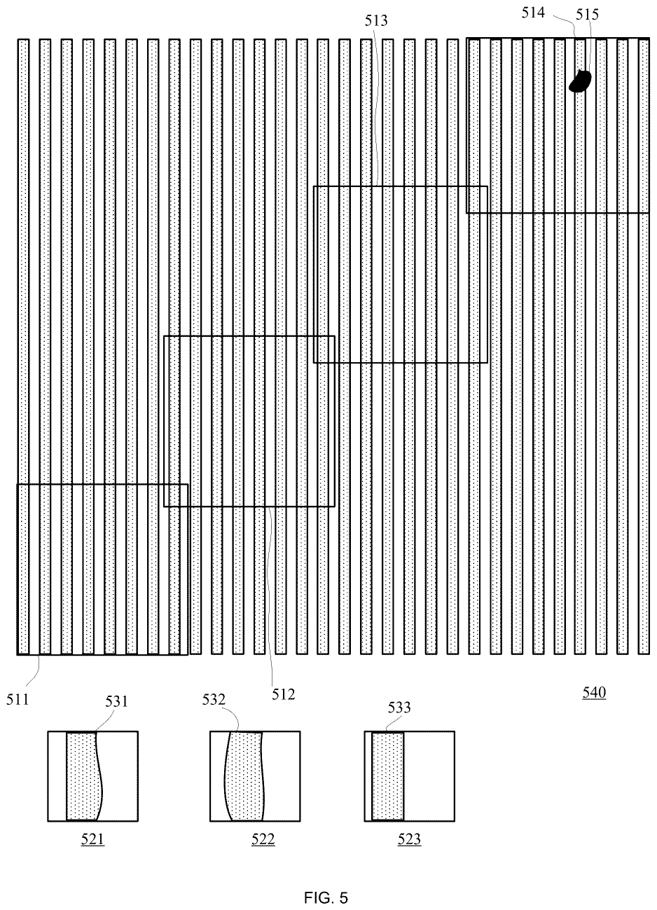

According to an embodiment, method 400 is used when a region of interest that should be scanned is covered by the tiles, see for example FIG. 5.

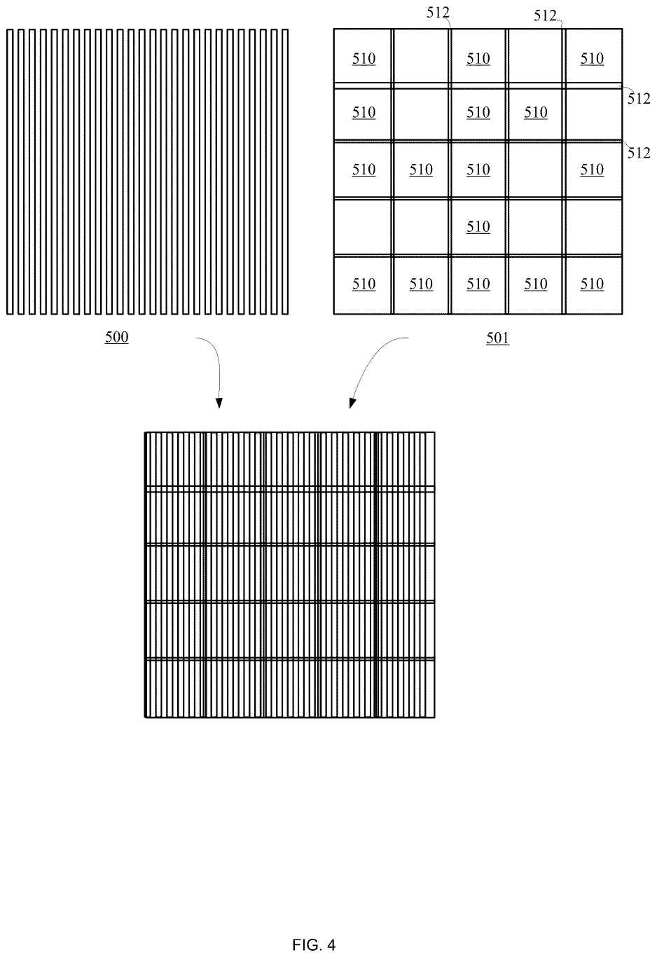

According to an embodiment, method 400 is used to determine, by the location circuit, a location of a suspected defect positioned within a target tile of the tiles by determining locations of location error prone tiles that span between the reference tile and the target tile. In this case the overall area covered by the tiles may be a fraction of a rectangular region that includes the reference tile, the error prone tiles and the target tile (which is one of the error prone tiles). See for example FIG. 4.

According to an embodiment, method 400 is executed, at least in part by a SEM, and step 410 further includes generating the SEM images of the tiles.

According to an embodiment, step 410 includes:
a. Step 404 of scanning, by SEM optics, the tiles of the sample with an electron beam.
b. Step 406 of detecting, by a detection unit, particles emitted due to the scan and generating detection signals indicative of the structural elements within the tiles of the sample.
c. Step 408 of generating, by an image processor, the SEM images of the tiles based on the detection signals.

FIG. 4 illustrates an example of region of interest 500, a scheme 501 for partitioning the region of interest of tiles to define overlap areas 518, and tiles 510 that include the overlap areas 518.

FIG. 5 illustrates an example of a rectangular region 540, reference tile 511, and three error prone tiles—including first error prone tile 512, second error prone tile 513 and target tile 514 that includes a suspected defect 515.

There are three overlap areas—first overlap area 521 (between reference tile 511 and first error prone tile 512), second overlap area 522 (between first error prone tile 512 and second error prone tile 513), and third overlap area 523 (between second error prone tile 512 and target tile 514).

The determination of the location of suspected defect 515 includes:
a. Determining the location of the first error prone tile 512 based on the known location of the reference tile 511, a process variation that appears in first overlap segment 531 of first overlap area 521, and a presence of the first overlap segment 531 within the reference tile 511 and the first error prone tile 512.
b. Determining the location of the second error prone tile 513 based on the known location of the reference tile 511 (which was used to determine the location of the first error prone tile 512), a process variation that appears in second overlap segment 532 of second overlap area 522, and a presence of the second overlap segment 532 within the first error prone tile 512 and the second error prone tile 513.
c. Determining the location of the target tile 514 based on the known location of the reference tile 511 (which was used to determine the location of the first error prone tile 512 and then of the second error prone tile 513), a process variation that appears in third overlap segment 533 of third overlap area 523, and a presence of the third overlap segment 533 within the second error prone tile 513 and target tile 514.

Once the location of the reference tile is known, the location of the suspected defect within the tile is also determined.

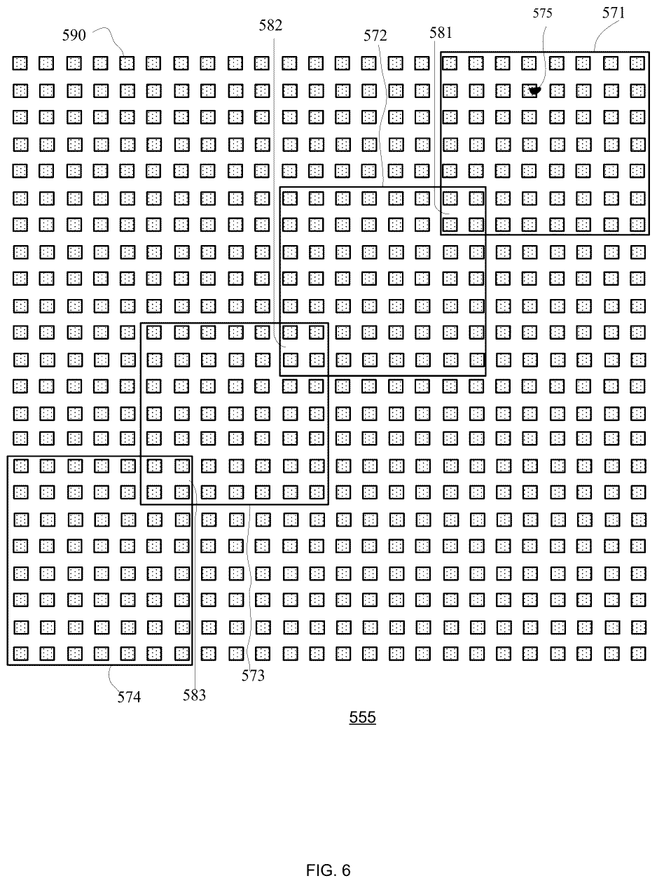

FIG. 6 illustrates an example of a rectangular region 555, reference tile 571, and three error prone tiles, including first error prone tile 572, second error prone tile 573 and target tile that includes a suspected defect 575.

In FIG. 6 the rectangular region 555 includes a two-dimension arrays of spaced apart rectangular elements 590 (while any shaped spaced apart elements may be provided, for example round, elliptical, having more than four facets, and the like).

There are three overlap areas—first overlap area 581 (between reference tile 571 and first error prone tile 572), second overlap area 582 (between first error prone tile 572 and second error prone tile 573), and third overlap area 583 (between second error prone tile 573 and target tile 574). Each overlap region is illustrated as including two by two spaced apart rectangular elements 590—although the number of spaced apart rectangular elements may differ than four.

The determination of the location of suspected defect 515 is applicable, mutatis mutandis to the detection of the location of suspected defect 575.

In the foregoing detailed description, numerous specific details are set forth in order to provide a thorough understanding of the embodiments of the disclosure.

However, it will be understood by those skilled in the art that the present embodiments of the disclosure may be practiced without these specific details. In other instances, well-known methods, procedures, and components have not been described in detail so as not to obscure the present embodiments of the disclosure.

The subject matter regarded as the embodiments of the disclosure is particularly pointed out and distinctly claimed in the concluding portion of the specification. The embodiments of the disclosure, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the disclosure may for the most part, be implemented using optical and/or electronic components and circuits known to those skilled in the art, details will not be explained in any greater extent than that considered necessary as illustrated above, for the understanding and appreciation of the underlying concepts of the present embodiments of the disclosure and in order not to obfuscate or distract from the teachings of the present embodiments of the disclosure.

Any reference in the specification to a method should be applied mutatis mutandis to a system capable of executing the method and should be applied mutatis mutandis to a computer program product that stores instructions that once executed result in the execution of the method.

Any reference in the specification to a system should be applied mutatis mutandis to a method that may be executed by the system should be applied mutatis mutandis to a computer program product that stores instructions that can be executed by the system.

Any reference in the specification to a computer program product should be applied mutatis mutandis to a method that may be executed when executing instructions stored in the computer program product and should be applied mutandis to a system that is configured to executing instructions stored in the computer program product.

The term and/or means additionally or alternatively. For example, A and/or B means only A, or only B or A and B.

In the foregoing specification, the embodiments of the disclosure have been described with reference to specific examples of embodiments. It will, however, be evident that various modifications and changes may be made therein without departing from the broader spirit and scope of the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Any reference to the term “comprising” or “having” or “including” should be applied mutatis mutandis to “consisting” and additionally or alternatively should be applied mutatis mutandis to “consisting essentially of”.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above-described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also, for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

Also, for example, the examples, or portions thereof, may implemented as soft or code representations of physical circuitry or of logical representations convertible into physical circuitry, such as in a hardware description language of any appropriate type.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to embodiments containing only one such element, even when the same claim includes the introductory phrases “one or more” or “at least one” and indefinite articles such as “a” or “an.” The same holds true for the use of definite articles. Unless stated otherwise, terms such as “first“ and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the embodiments have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A system for navigation accuracy, the system comprising:
a memory unit configured to store scanning electron microscope (SEM) images of tiles of a sample, the tiles belong to a periodic array of structural elements that exhibit at least one microscopic dimension, wherein the tiles comprise a reference tile of a known location and location error prone tiles, wherein there is an overlap region between each set of adjacent tiles, each overlap region comprises an overlap segment of one of the structural elements; and
a location circuit that comprises one or more integrated circuits, and is configured to determine locations of the tiles based on locations of sets of adjacent tiles;
wherein the location circuit is configured to determine a location of each set based on (i) a process variation that appears in an overlap segment of the set, (ii) the known location, and (iii) a presence of the overlap segment of the set within each tile of the set.

2. The system according to claim 1, wherein the location circuit is configured to determine the process variation, for each set, by applying a spatial frequency transform on pixels of the overlap region of the set.

3. The system according to claim 2, wherein the spatial frequency transform is a two-dimensional spatial frequency transform.

4. The system according to claim 1, wherein the location circuit is configured to determine, for each set, (a) a first coordinate of the overlap segment of the set based on the process variation that appears in the overlap segment of the set, and (b) a second coordinate of the overlap segment of the set based on the presence of the overlap segment of the set within each tile of the set.

5. The system according to claim 4, wherein the structural elements are arranged in a repeating pattern along a single axis of repetition, wherein the second coordinate is a single axis of repetition coordinate.

6. The system according to claim 1, wherein the location circuit is configured to determine a location of a suspected defect positioned within a target tile of the tiles by determining locations of location error prone tiles that span between the reference tile and the target tile.

7. The system according to claim 1, further comprising:
SEM optics that is configured to scan the tiles of the sample with an electron beam;
a sensing unit that is configured to detect particles emitted due to the scan and generate detection signals indicative of the structural elements within the tiles of the sample; and
an image processor that is configured to generate the SEM images of the tiles based on the detection signals.

8. A method for navigation accuracy, the method comprising:
obtaining scanning electron microscope (SEM) images of tiles of a sample, the tiles belong to a periodic array of structural elements that exhibit at least one microscopic dimension, wherein the tiles comprise a reference tile of a known location and location error prone tiles, wherein there is an overlap region between each set of adjacent tiles, each overlap region comprises an overlap segment of one of the structural elements;
determining, for each set and by a location circuit that comprises one or more integrated circuits, the locations of the set based on (i) a process variation that appears in an overlap segment of the set, (ii) the known location, and (iii) a presence of the overlap segment of the set within each tile of the set; and
determining, the locations of the tiles based on a location of each set.

9. The method according to claim 8, comprising determining, by the location circuit, the process variation, for each set, by applying a spatial frequency transform on pixels of the overlap region of the set.

10. The method according to claim 9, wherein the spatial frequency transform is a two-dimensional spatial frequency transform.

11. The method according to claim 8, comprising determining, for each set and by the location circuit, (a) a first coordinate of the overlap segment of the set based on the process variation that appears in the overlap segment of the set, and (b) a second coordinate of the overlap segment of the set based on the presence of the overlap segment of the set within each tile of the set.

12. The method according to claim 11, wherein the structural elements are arranged in a repeating pattern along a single axis of repetition, wherein the second coordinate is a single axis of repetition coordinate.

13. The method according to claim 8, comprising determining, by the location circuit, a location of a suspected defect positioned within a target tile of the tiles by determining locations of location error prone tiles that span between the reference tile and the target tile.

14. The method according to claim 8, further comprising:
scanning, by SEM optics, the tiles of the sample with an electron beam;
detecting, by a detection unit, particles emitted due to the scan and generating detection signals indicative of the structural elements within the tiles of the sample; and
generating, by an image processor, the SEM images of the tiles based on the detection signals.

15. A non-transitory computer readable medium for navigation accuracy, the non-transitory computer readable medium stores instructions that once executed by a system, cause the system to:
obtain scanning electron microscope (SEM) images of tiles of a sample, the tiles belong to a periodic array of structural elements that exhibit at least one microscopic dimension, wherein the tiles comprise a reference tile of a known location and location error prone tiles, wherein there is an overlap region between each set of adjacent tiles, each overlap region comprises an overlap segment of one of the structural elements;
determine, for each set and by a location circuit of the system, the locations of the set based on (i) a process variation that appears in an overlap segment of the set, (ii) the known location, and (iii) a presence of the overlap segment of the set within each tile of the set; wherein the location circuit comprises one or more integrated circuits; and
determine the locations of the tiles based on a location of each set.

16. The non-transitory computer readable medium according to claim 15, that further stores instructions that once executed by the location circuit cause the location circuit to determine the process variation, for each set, by applying a spatial frequency transform on pixels of the overlap region of the set.

17. The non-transitory computer readable medium according to claim 16, that further stores instructions that once executed by the location circuit cause the location circuit to determine, for each set, (a) a first coordinate of the overlap segment of the set based on the process variation that appears in the overlap segment of the set, and (b) a second coordinate of the overlap segment of the set based on the presence of the overlap segment of the set within each tile of the set.

18. The non-transitory computer readable medium according to claim 17, wherein the structural elements are arranged in a repeating pattern along a single axis of repetition, wherein the second coordinate is a single axis of repetition coordinate.

19. The non-transitory computer readable medium according to claim 15, that further stores instructions that once executed by the location circuit, cause the location circuit to determine a location of a suspected defect positioned within a target tile of the tiles by determining locations of location error prone tiles that span between the reference tile and the target tile.

20. The non-transitory computer readable medium according to claim 15, that further stores instructions that once executed by the system cause the system to:
scan, by SEM optics of the system, the tiles of the sample with an electron beam;
detect, by a sensing unit of the system, particles emitted due to the scan and generating detection signals indicative of the structural elements within the tiles of the sample; and
generate, by an image processor of the system, the SEM images of the tiles based on the detection signals.
